(19) United States
(12) Patent Application Publication
(10) Pub. No.: US 2026/0323836 A1
(43) Pub. Date: Oct. 15, 2026

(54) SEMICONDUCTOR PACKAGE MODULE, SEMICONDUCTOR SYSTEM AND METHOD FOR FABRICATION OF THE SAME

(71) Applicant: USI Science and Technology (Shenzhen) Co., Ltd., Guangdong Province (CN)

(72) Inventor: LI-CHENG SHEN, Guangdong Province (CN)

(21) Appl. No.: 19/632,446

(22) Filed: Mar. 30, 2026

(30) Foreign Application Priority Data
Apr. 10, 2025 (CN) 202510446111.3

(51) Int. Cl. H05K 1/183; H05K 1/181; H05K 3/20; H05K 3/28; H05K 3/32; H05K 3/00

(52) U.S. Cl. CPC H05K 1/183; H05K 1/181; H05K 3/202; H05K 3/284; H05K 3/32; H05K 3/0026; H05K 2201/10318; H05K 2201/10977; H05K 2203/1327

(57) ABSTRACT

A semiconductor package module, a semiconductor system and a method for fabrication of the same are provided. The semiconductor package module includes a circuit substrate, a metal substrate and a plurality of metal pillars. The circuit substrate includes a first opening, and two opposite sides of the circuit substrate is connected to each other through the first opening. The metal substrate is disposed on a surface of the circuit substrate, while the metal substrate includes a second opening. Two opposite sides of the metal substrate is connected to each other through the second opening, and the first opening of the circuit substrate and the second opening of the metal substrate do not overlap each other. The metal pillars are disposed on the surface of the circuit substrate and are located inside the second opening of the metal substrate.

### RELATED APPLICATIONS

This application claims priority to China Application Serial Number 202510446111.3, filed April 10, 2025, which is herein incorporated by reference in its entirety.

### BACKGROUND

### Technical Field

The present disclosure relates to a semiconductor package module and the method for fabrication of the same and relates to a semiconductor system using the semiconductor package module.

### Description of Related Art

With the trend of increasing density and reducing dimension of the semiconductor packaging, the demand for heat dissipation of semiconductor package modules is gradually increasing. In order to improve the heat dissipation of electronic components in semiconductor package modules, the primary method is to set a heat dissipation plate with a heat dissipation metal bulk (e.g., an embedded T-coin) on one side of the circuit substrate. The heat dissipation metal bulk on the heat dissipation plate may be embedded in the circuit substrate and under the electronic component so as to directly touch the bottom of the electronic component, thereby improving the heat dissipation of the electronic component.

However, since the heat dissipation metal bulk should be embedded in the circuit substrate according to the aforementioned method, the flatness of the interface between the circuit substrate and the heat dissipation plate is difficult to be controlled during the process. Thus, the stability of subsequent installation of electronic components on the circuit substrate (e.g., die-bonding or wire-bonding) may be affected, so that the yield of semiconductor package modules is hard to be improved.

### SUMMARY

Accordingly, the disclosure is to provide a semiconductor package module so as to increase the yield of the semiconductor package module.

At least one embodiment of the disclosure provides a semiconductor system using the aforementioned semiconductor package module.

At least one embodiment of the disclosure provides a method for fabrication of the aforementioned semiconductor package module.

At least one embodiment of the disclosure provides the method for fabrication of the semiconductor package module including providing a circuit substrate, and the circuit substrate includes a first surface. The method includes providing a metal substrate, and the metal substrate includes a second surface. The method includes removing a part of the circuit substrate to form at least a first opening on the circuit substrate, and two opposite sides of the circuit substrate are connected to each other through the first opening. The method includes removing a part of the metal substrate to form at least a second opening on the metal substrate, and two opposite sides of the metal substrate is connected to each other through the second opening. The method includes disposing a plurality of first metal pillars on the first surface of the circuit substrate and disposing the metal substrate on the first surface of the circuit substrate after the first opening and the second opening is formed. The second surface of the metal substrate faces the first surface of the circuit substrate, where the first opening of the circuit substrate and the second opening of the metal substrate do not overlap each other. The plurality of first metal pillars are located inside the second opening of the metal substrate.

At least one embodiment of the disclosure provides the method for fabrication of the semiconductor package module including providing a circuit substrate, and the circuit substrate includes a first surface. The method includes providing a metal substrate, and the metal substrate includes a second surface. The method includes removing a part of the circuit substrate to form at least an opening on the circuit substrate, and two opposite sides of the circuit substrate are connected to each other through the opening. The method includes disposing a plurality of metal pillars on the first surface of the circuit substrate and disposing the circuit substrate on the second surface of the metal substrate. The first surface of the circuit substrate backs onto the second surface of the metal substrate, where the opening of the circuit substrate and the plurality of metal pillars do not overlap each other.

At least one embodiment of the disclosure provides a semiconductor package module which includes a circuit substrate, a metal substrate and a plurality of first metal pillars. The circuit substrate includes a first opening, and two opposite sides of the circuit substrate are connected to each other through the first opening. The metal substrate is disposed on a first surface of the circuit substrate, where a second surface of the metal substrate faces the circuit substrate. The metal substrate includes a second opening, where two opposite sides of the metal substrate are connected to each other through the second opening. The second opening of the metal substrate and the first opening of the circuit substrate do not overlap each other. The plurality of first metal pillars are disposed on the first surface of the circuit substrate and located inside the second opening of the metal substrate.

At least one embodiment of the disclosure provides a semiconductor package module which includes a circuit substrate, a metal substrate and a plurality of metal pillars. The circuit substrate includes a first surface and a first opening, where two opposite sides of the circuit substrate are connected to each other through the first opening. The metal substrate is disposed on the circuit substrate, where a second surface of the metal substrate faces the circuit substrate. The plurality of metal pillars are disposed on the first surface of the circuit substrate, where the first surface of the circuit substrate and the second surface of the metal substrate are located at two opposite sides of the circuit substrate. The first opening of the circuit substrate and the plurality of metal pillars do not overlap each other.

At least one embodiment of the disclosure provides a semiconductor system which includes the aforementioned semiconductor package module and a main board. The semiconductor package module further includes an encapsulation layer disposed on the first surface of the circuit substrate and encapsulating the plurality of metal pillars. An edge surface of the plurality of metal pillars is exposed on a top surface of the encapsulation layer, and the top surface backs onto the circuit substrate. The main board is disposed on the top surface of the encapsulation layer, where the main board is connected to the edge surface of the plurality of metal pillars. The main board is electrically connected to the circuit substrate through the plurality of metal pillars.

At least one embodiment of the disclosure provides a semiconductor system which includes the aforementioned semiconductor package module and a main board disposed on the metal substrate. The metal substrate is located between the circuit substrate and the main board, and the main board is electrically connected to the circuit substrate through the plurality of first metal pillars.

According to the aforementioned embodiments, the metal substrate of at least one embodiment of the disclosure is disposed on one of the surfaces of the circuit substrate, and the metal substrate directly touches the surface of the circuit substrate. The circuit substrate includes a plurality of openings which the two opposite sides of the circuit substrate is connected to each other through, while the metal substrate covers one end of each opening. As a result, when the electronic components are disposed on the surface of the metal substrate and located inside the openings of the circuit substrate, the metal substrate may provide the heat dissipation path which is advantage for increasing the heat dissipation efficiency of the semiconductor package module. Therefore, embedding the metal bulks inside the circuit substrate to improve the heat dissipation of the semiconductor package module is unnecessary. Thus, the uneven interface which is caused by the embedded metal bulks and is located between the circuit substrate and the metal substrate for heat dissipation may be prevented, thereby improving the assembly yield of the semiconductor package module.

### BRIEF DESCRIPTION OF THE DRAWINGS

FIGS. 1A to 1D illustrate cross-sectional views of a semiconductor package module in accordance with one embodiment of the present disclosure.

FIGS. 2A to 2C illustrate cross-sectional views of a semiconductor package module in accordance with one embodiment of the present disclosure.

FIG. 3A illustrates a cross-sectional view of a semiconductor package module in accordance with one embodiment of the present disclosure.

FIG. 3B illustrates a bottom view of a semiconductor package module in accordance with one embodiment of the present disclosure.

FIGS. 4A to 4F illustrate cross-sectional views of a semiconductor package module in accordance with another embodiment of the present disclosure.

FIG. 5 illustrates a cross-sectional view of a semiconductor package module in accordance with another embodiment of the present disclosure.

FIG. 6 illustrates a cross-sectional view of a semiconductor system in accordance with one embodiment of the present disclosure.

FIG. 7 illustrates a cross-sectional view of a semiconductor system in accordance with another embodiment of the present disclosure.

### DETAILED DESCRIPTION

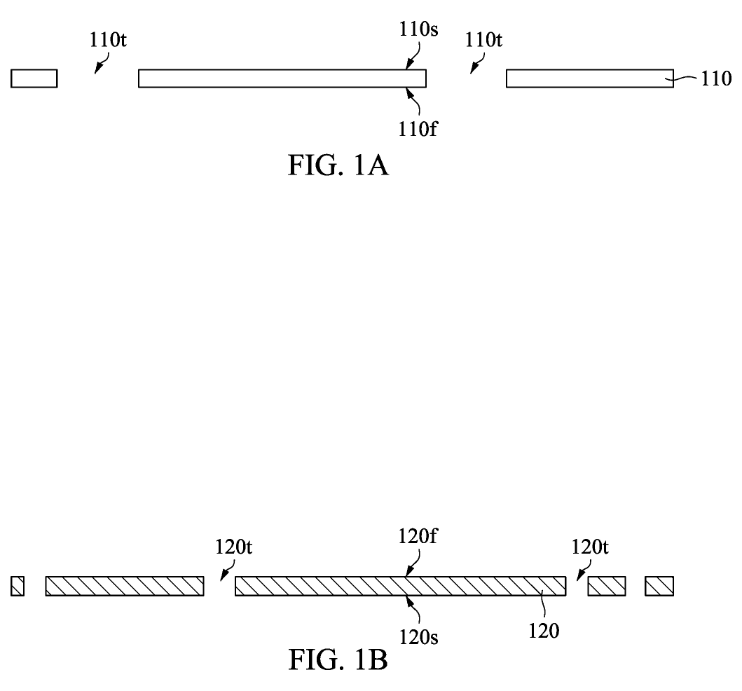

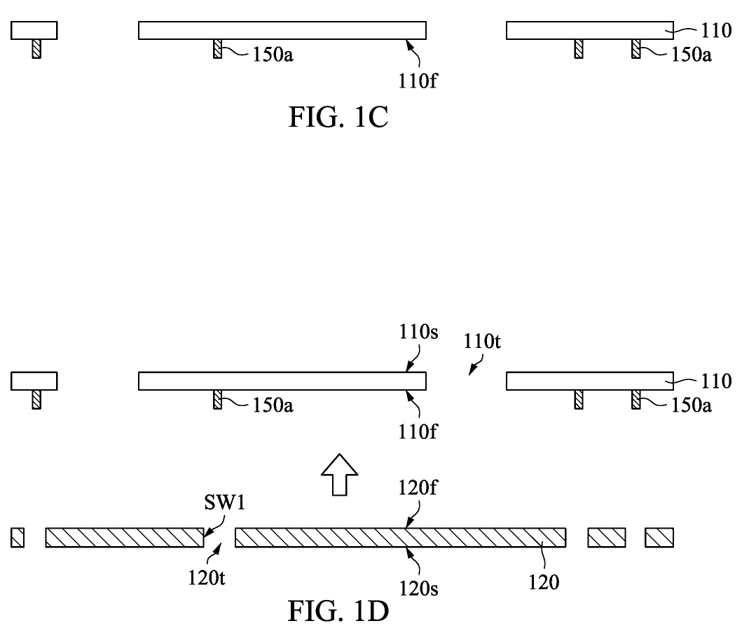

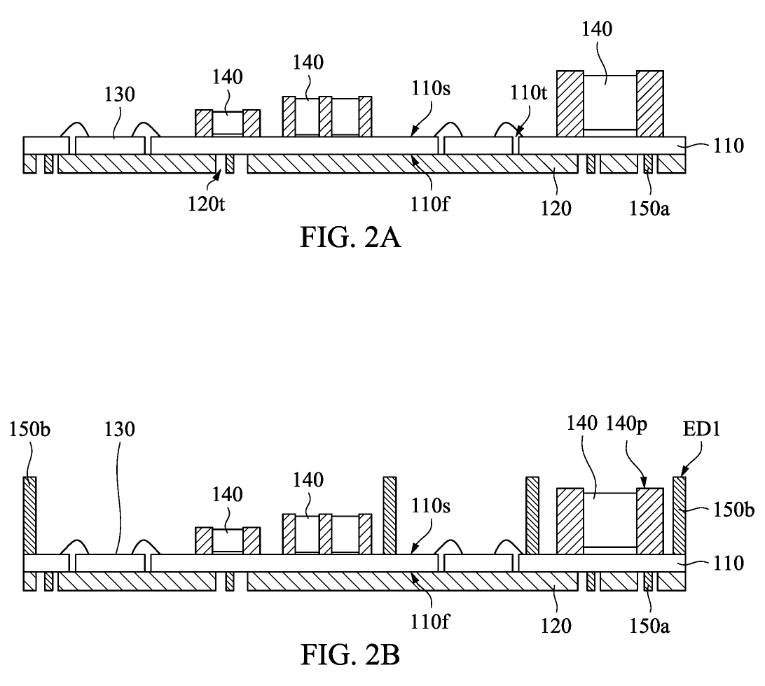

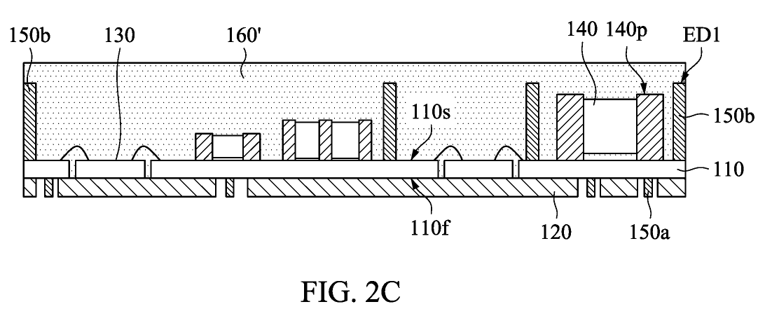

A method for fabrication of the semiconductor package module is disclosed, while FIGS. 1A to 1D and 2A to 2C illustrate sequent steps of this method in accordance with at least one embodiment of present disclosure. Referring to FIG. 1A, firstly, a circuit substrate 110 is provided. The circuit substrate 110 includes a surface 110f and a surface 110s opposite to the surface 110f. Next, a part of the circuit substrate 110 may be removed to form at least one opening 110t by laser cutting, laser grooving or other similar methods. Two opposite sides of the circuit substrate 110 are connected to each other through the openings 110t.

In addition, referring to FIG. 1B, the method for fabrication of the semiconductor package module includes providing a metal substrate 120. The metal substrate 120 includes a surface 120f and a surface 120s opposite to the surface 120f, while the metal substrate 120 may include copper (e.g., Cu-Fe-P alloys, Cu-Cr-Zr alloys, Cu-Ni-Si alloys, Cu-Cr-Sn alloys or Cu-Ni-Sn alloys) or similar alloys. Next, a part of the metal substrate 120 may be removed to form at least one opening 120t by laser cutting, laser grooving or other similar methods. Two opposite sides of the metal substrate 120 are connected to each other through the openings 120t.

It is worth mentioning, in other embodiments, the openings 120t may be formed on the metal substrate 120 by preforming. Next, referring to FIG. 1C, a plurality of metal pillars 150a are disposed on the surface 110f of the circuit substrate 110 by surface mount technology (SMT), such as soldering. However, although the metal pillars 150a are disposed on the surface 110f of the circuit substrate 110 after the openings 110t are formed in this embodiment, the disclosure is not limited to the embodiment. That is, the metal pillars 150a may be disposed on the surface 110f of the circuit substrate 110 before the openings 110t are formed on the circuit substrate 110 in other embodiments.

Referring to FIG. 1D, the metal substrate 120 is disposed on the surface 110f of the circuit substrate 110 after the openings 110t and the openings 120t are formed, while the surface 120f of the metal substrate 120 faces the surface 110f of the circuit substrate 110. In addition, the openings 110t of the circuit substrate 110 and the openings 120t of the metal substrate 120 do not overlap each other, and the metal pillar 150a is located inside the opening 120t of the metal substrate 120. It is worth mentioning, the metal pillars 150a do not touch the inner sides of the openings 120t directly. Specifically, the metal pillars 150a are completely spaced from an inner wall SW1 of the opening 120t of the metal substrate 120.

Although the metal substrate 120 is disposed on the surface 110f of the circuit substrate 110 after the metal pillars 150a are disposed on the surface 110f of the circuit substrate 110, the disclosure is not limited to the embodiment. That is, the metal substrate 120 may be disposed on the surface 110f of the circuit substrate 110 before the plurality of metal pillars 150a are disposed on the surface 110f of the circuit substrate 110 in other embodiments.

Referring to FIG. 2A, in the embodiment, the method for fabrication of the semiconductor package module further includes disposing an electronic component 130 on the surface 120f of the metal substrate 120. The electronic component 130 is located inside the opening 110t of the circuit substrate 110 and is electrically connected to the circuit substrate 110. It is worth mentioning, the electronic component 130 does not touch the inner side of the opening 110t directly. Although there is no direct connection between the electronic component 130 and the inner side of the opening 110t, the electronic component 130 may be electrically connected to the circuit substrate 110 by other methods, such as wire-bonding.

Furthermore, the method for fabrication of the semiconductor package module further includes disposing an electronic component 140 on the surface 110s of the circuit substrate 110 after the electronic component 130 is disposed on the surface 120f of the metal substrate 120. The surface 110f and the surface 110s are located at two opposite sides of the circuit substrate 110, and the electronic component 140 may be electrically connected to the circuit substrate 110 by SMT methods.

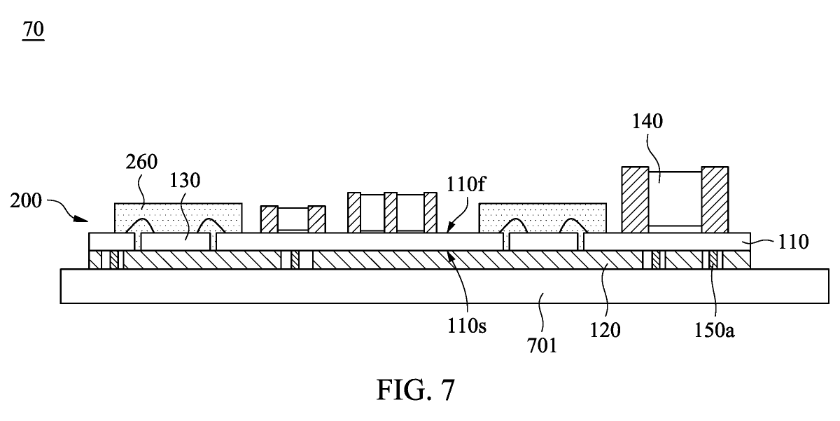

Referring to FIG. 2B, in the embodiment, the method for fabrication of the semiconductor package module further includes disposing a plurality of metal pillars 150b on the surface 110s after the electronic component 140 is disposed on the surface 110s of the circuit substrate 110. An edge surface ED1 of each of the metal pillars 150b protrudes from a plane 140p of the electronic component 140, while the edge surface ED1 and the plane 140p back onto the circuit substrate 110. It is worth mentioning, although the step of disposing the plurality of metal pillars 150b on the surface 110s is included in this embodiment, the disclosure is not limited to the embodiment. In other embodiments, only the metal pillars 150a are disposed but without the metal pillars 150b (referring to FIG. 7).

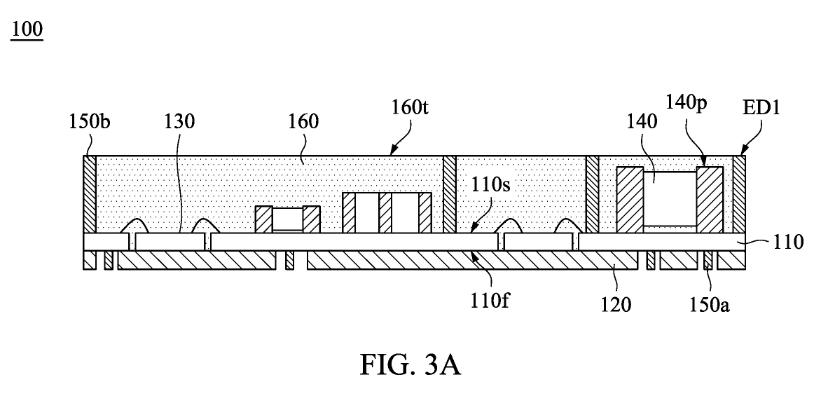

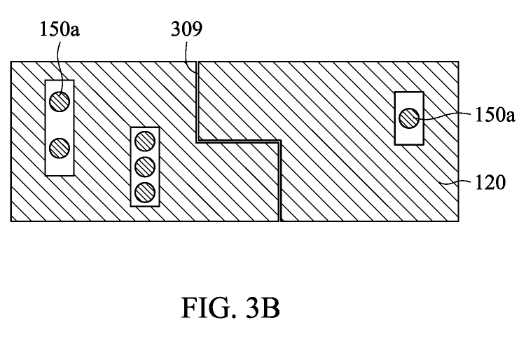

Referring to FIG. 2C, in the embodiment, the method for fabrication of the semiconductor package module further includes disposing an encapsulation material 160’ on the surface 110s to encapsulate the electronic component 130, the electronic component 140 and the metal pillars 150b after the metal pillars 150b are disposed on the surface 110s of the circuit substrate 110. Furthermore, the encapsulation material 160’ is ground by laser cutting or mechanical grinding to form an encapsulation layer 160 (denoted in FIG. 3A) after the encapsulation material 160’ is disposed, while the encapsulation layer 160 covers the electronic component 130 and the electronic component 140. In addition, the encapsulation layer 160 encapsulates the metal pillars 150b, but the edge surface ED1 of the metal pillar 150b is exposed on a top surface 160t of the encapsulation layer 160, which backs onto the circuit substrate 110. Thus, the semiconductor package module 100 in FIG. 3A is approximately completed.

Referring to FIG. 3A, the semiconductor package module 100 includes the circuit substrate 110, the metal substrate 120 and the plurality of metal pillars 150a. The circuit substrate 110 includes the openings 110t, and two opposite sides of the circuit substrate 110 are connected to each other through the openings 110t. Specifically, the surface 110f and the surface 110s of the circuit substrate 110 are connected to each other through the openings 110t of the circuit substrate 110, while the surface 110f and the surface 110s are located at two opposite sides of the circuit substrate 110 separately.

The metal substrate 120 is disposed on the surface 110f of the circuit substrate 110, as shown in FIG. 3A, the surface 120f of the metal substrate 120 faces the circuit substrate 110. The metal substrate 120 includes the openings 120t, and two opposite sides of the metal substrate 120 are connected to each other through the openings 120t. Specifically, the surface 120f and the surface 120s of the metal substrate 120 are connected to each other through the openings 120t of the metal substrate 120, while the surface 120f and the surface 120s are located at two opposite sides of the metal substrate 120 separately. It is worth mentioning, the openings 120t of the metal substrate 120 do not overlap the openings 110t of the circuit substrate 110. In other words, the openings 120t of the metal substrate 120 are not aligned to the openings 110t of the circuit substrate 110.

The metal pillars 150a are disposed on the surface 110f of the circuit substrate 110 and inside the openings 120t of the metal substrate 120. In addition, the metal pillars 150a are completely spaced from the inner side wall SW1 (denoted in FIG. 1D) of the openings 120t of the metal substrate 120 in the embodiment. It is worth mentioning, the openings 120t of the metal substrate 120 are aligned to the metal pillars 150a one on one in the embodiment of FIG. 3A, that is, one metal pillar 150a is disposed inside one opening 120t. However, in various embodiments of the disclosure, the quantity of the metal pillars 150a disposed inside one opening 120t of the metal substrate 120 is not limited to one. In other words, in some embodiments, more than one metal pillar 150a, such as three metal pillars 150a, may be disposed inside one opening 120t of the metal substrate 120 (shown in FIG. 3B).

Referring to FIG. 3B, the metal substrate 120 may further include at least one trench 309, and two opposite sides of the metal substrate 120 are connected to each other (i.e., the surface 120f and the surface 120s of the metal substrate 120 are connected to each other) through the trench 309. As shown in FIG. 3B, in the embodiment, at least two regions (i.e., the left and the right regions in FIG. 3B) of the metal substrate 120 are completely spaced from each other by the trench 309.

In the embodiment, the semiconductor package module 100 further includes the electronic component 130 and the electronic component 140. The electronic component 130 is disposed on the metal substrate 120 and located inside the opening 110t of the circuit substrate 110. On the other hand, the electronic component 140 is disposed on the surface 110s of the circuit substrate 110. The electronic component 130 and the electronic component 140 are electrically connected to the circuit substrate 110. Specifically, the electronic component 130 may be electrically connected to the circuit substrate 110 through wire-bonding, while the electronic component 140 may be electrically connected to the circuit substrate 110 through SMT. It is worth mentioning, both of the electronic component 130 and the electronic component 140 are not electrically connected to the metal substrate 120 in the embodiment.

The electronic component 130 and the electronic component 140 may be active components, such as transistors, or may be passive components, such as capacitors or inductors. For example, in the embodiment, the electronic component 130 is a packaged chip or an unpackaged die, while the electronic component 140 is a capacitor or an inductor. However, the sorts of the electronic component 130 and the electronic component 140 are not limited to the embodiment.

It is worth mentioning, the openings 110t of the circuit substrate 110 are aligned to the electronic component 130 one on one in the embodiment of FIG. 3A, that is, one electronic component 130 is disposed inside one opening 110t. However, in various embodiments of the disclosure, the quantity of the electronic component 130 disposed inside the opening 110t of the circuit substrate 110 is not limited to one. In other words, in some embodiments, more than one electronic component 130, such as three electronic components 130, may be disposed inside one opening 110t of the circuit substrate 110.

The semiconductor package module 100 further includes the plurality of metal pillars 150b, and the metal pillars 150b are disposed on the surface 110s of the circuit substrate 110. Each of the metal pillars 150b has the edge surface ED1, while the electronic component 140 has the plane 140p. The edge surface ED1 and the plane 140p back onto the circuit substrate 110, that is, the edge surface ED1 and the plane 140p are far away from the surface 110s of the circuit substrate 110. In addition, the edge surface ED1 of each of the metal pillars 150b protrudes from the plane 140p of the electronic component 140. In other words, the height of the metal pillars 150b is larger than the height of the electronic component 140.

The semiconductor package module 100 further includes the encapsulation layer 160, which is disposed on the surface 110s of the circuit substrate 110 and covers the electronic component 130 and the electronic component 140. The encapsulation layer 160 encapsulates the metal pillars 150b and has the top surface 160t backing onto the circuit substrate 110, while the edge surface ED1 of the metal pillar 150b is exposed on the top surface 160t of the encapsulation layer 160. As a result, the semiconductor package module 100 may be electrically connected to other components, such as main board, through the edge surface ED1 of the metal pillar 150b.

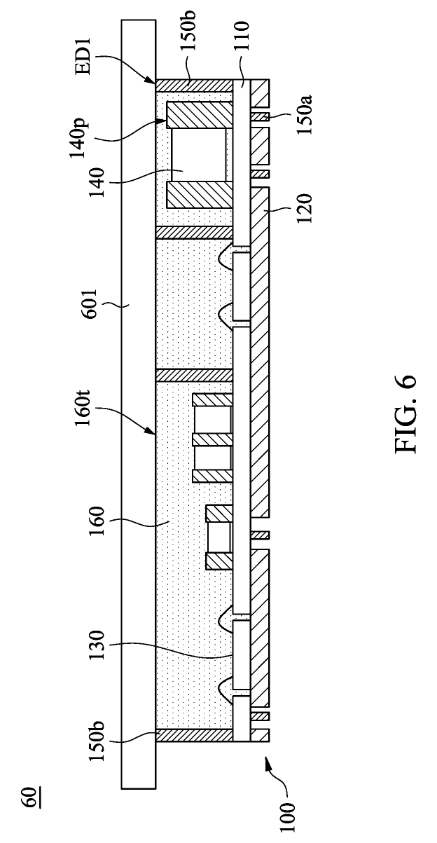

For example, referring to a semiconductor system 60 illustrated in FIG. 6, the semiconductor system 60 includes the aforementioned semiconductor package module 100 and a main board 601. The main board 601 is disposed on the top surface 160t of the encapsulation layer 160, while the main board 601 is connected to the edge surface ED1 of the metal pillar 150b. That is, the circuit substrate 110 is located between the main board 601 and the metal substrate 120. In the embodiment, the main board 601 may be electrically connected to the circuit substrate 110 through the metal pillar 150b since the metal pillar 150b is electrically connected to the circuit substrate 110.

However, the disposition of the encapsulation layer of the disclosure is not limited to the aforementioned embodiments. Referring to another semiconductor system 70 illustrated in FIG. 7, the semiconductor system 70 includes another semiconductor package module 200 and a main board 701. The semiconductor package module 200 is similar to the semiconductor package module 100 and also includes the circuit substrate 110, the metal substrate 120, the electronic component 130, the electronic component 140 and the metal pillars 150a. However, the difference between the semiconductor package module 200 and the semiconductor package module 100 is that the semiconductor package module 200 excludes the metal pillars 150b. Thus, an encapsulation layer 260 of the semiconductor package module 200 may only encapsulate the electronic component 130 (or may only encapsulate the electronic component 130 and the electronic component 140).

As shown in FIG. 7, the metal substrate 120 is located between the circuit substrate 110 and the main board 701. The metal pillar 150a is located inside the opening 120t of the metal substrate 120, while two ends of the metal pillar 150a may be connected to the circuit substrate 110 and the main board 701 separately. Thus, the main board 701 is electrically connected to the circuit substrate 110 through the metal pillar 150a.

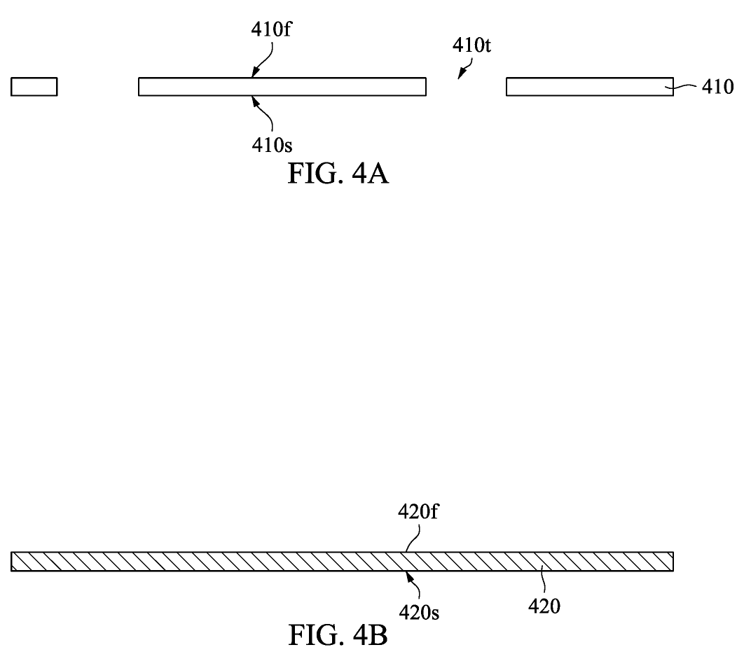

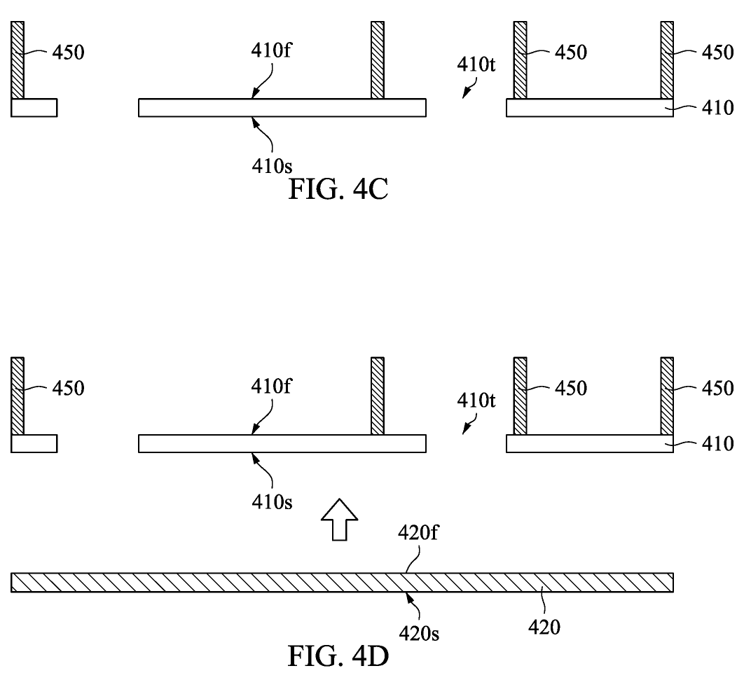

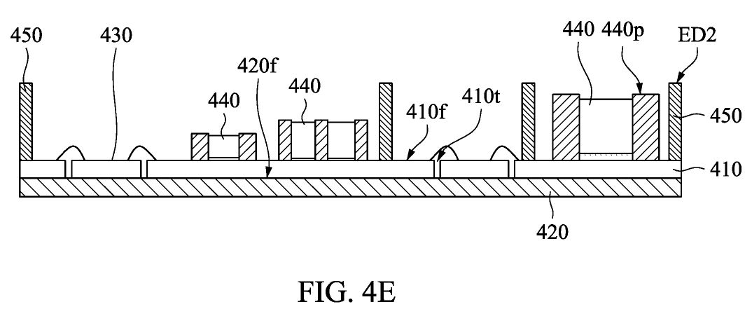

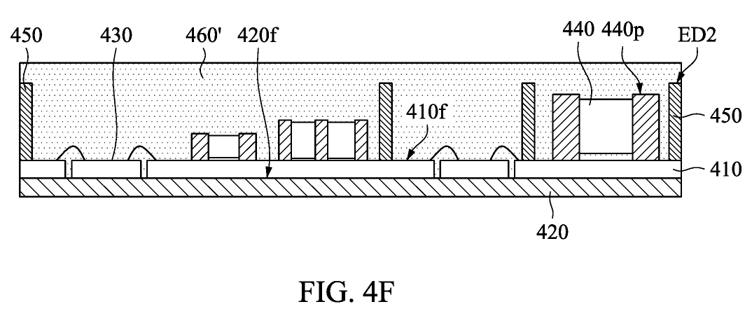

FIGS. 4A to 4F illustrate sequent steps of the method in accordance with another embodiment of present disclosure. Referring to FIG. 4A, firstly, a circuit substrate 410 is provided. The circuit substrate 410 includes a surface 410f and a surface 410s opposite to the surface 410f. Next, a part of the circuit substrate 410 may be removed to form at least one opening 410t by laser cutting, laser grooving or other similar methods. Two opposite sides of the circuit substrate 410 are connected to each other through the openings 410t. In addition, referring to FIG. 4B, the method for fabrication of the semiconductor package module includes providing a metal substrate 420. The metal substrate 420 includes a surface 420f and a surface 420s opposite to the surface 420f, and the metal substrate 420 may include copper (e.g., Cu-Fe-P alloys, Cu-Cr-Zr alloys, Cu-Ni-Si alloys, Cu-Cr-Sn alloys or Cu-Ni-Sn alloys) or similar alloys.

Referring to FIG. 4C, the method for fabrication of the semiconductor package module includes disposing a plurality of metal pillars 450 on the surface 410f of the circuit substrate 410. Referring to FIG. 4D, the circuit substrate 410 are disposed on the surface 420f of the metal substrate 420, while the surface 410f of the circuit substrate 410 backs onto the surface 420f of the metal substrate 420. Furthermore, the openings 410t of the circuit substrate 410 and the metal pillars 450 do not overlap each other.

It is worth mentioning, in various embodiments of the disclosure, the step that disposing the circuit substrate 410 on the surface 420f of the metal substrate 420 is not limited to follow the step that disposing the metal pillars 450 on the surface 410f of the circuit substrate 410. In some embodiments, the circuit substrate 410 may be disposed on the surface 420f of the metal substrate 420 before the metal pillars 450 are disposed on the surface 410f of the circuit substrate 410.

Referring to FIG. 4E, in the embodiment, the method for fabrication of the semiconductor package module further includes disposing an electronic component 430 on the surface 420f of the metal substrate 420 after the circuit substrate 410 is disposed on the surface 420f of the metal substrate 420. The electronic component 430 is located inside the opening 410t of the circuit substrate 410, and the electronic component 430 may be electrically connected to the circuit substrate 410 through wire-bonding.

In addition, the method for fabrication of the semiconductor package module further includes disposing an electronic component 440 on the surface 410f of the circuit substrate 410 after the circuit substrate 410 is disposed on the surface 420f of the metal substrate 420. The electronic component 440 may be electrically connected to the circuit substrate 410 by SMT. It is worth mentioning, each of the metal pillars 450 has an edge surface ED2, while the electronic component 440 has a plane 440p. The edge surface ED2 and the plane 440p back onto the circuit substrate 410, that is, both of the edge surface ED2 of the metal pillars 450 and the plane 440p of the electronic component 440 are far away from the surface 410f of the circuit substrate 410. Furthermore, the edge surface ED2 of each of the metal pillars 450 protrudes from the plane 440p of the electronic component 440.

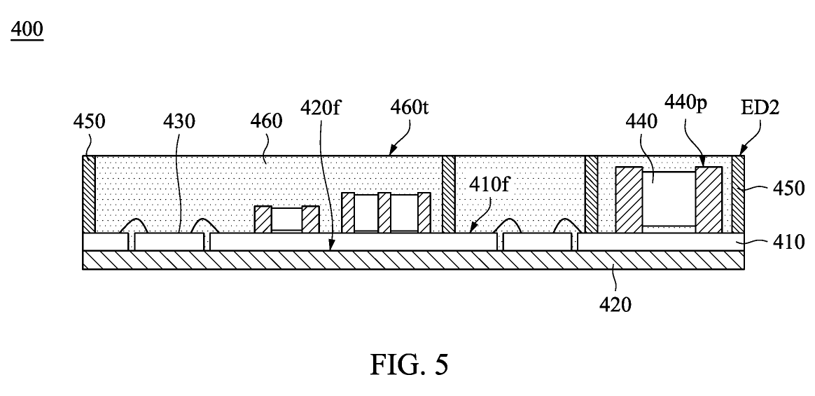

Referring to FIG. 4F, in the embodiment, the method for fabrication of the semiconductor package module further includes disposing an encapsulation material 460’ on the surface 410f to encapsulate the electronic component 430, the electronic component 440 and the metal pillars 450 after the electronic component 440 is disposed on the surface 410f of the circuit substrate 410. Furthermore, the encapsulation material 460’ is ground by laser cutting or mechanical grinding to form an encapsulation layer 460 (denoted in FIG. 5) after the encapsulation material 460’ is disposed, while the encapsulation layer 460 covers the electronic component 430 and the electronic component 440. In addition, the encapsulation layer 460 encapsulates the metal pillar 450, but the edge surface ED2 of the metal pillar 450 is exposed on a top surface 460t of the encapsulation layer 460, which backs onto the circuit substrate 410. Thus, a semiconductor package module 400 illustrated in FIG. 5 is approximately completed.

Referring to FIG. 5, the semiconductor package module 400 includes the circuit substrate 410 the metal substrate 420 and the plurality of metal pillars 450. The circuit substrate 410 includes openings 410t, and two opposite sides of the circuit substrate 410 are connected to each other through the openings 410t. Specifically, the surface 410f and the surface 410s of the circuit substrate 410 are connected to each other through the openings 410t of the circuit substrate 410, while the surface 410f and the surface 410s are located at two opposite sides of the circuit substrate 410 separately.

The metal substrate 420 is disposed on the circuit substrate 410, and the metal substrate 420 has the surface 420f and the surface 420s opposite to each other. As shown in FIG. 5, the surface 420f of the metal substrate 420 faces the circuit substrate 410. The metal pillars 450 are disposed on the surface 410f of the circuit substrate 410, while the surface 410f of the circuit substrate 410 and the surface 420f of the metal substrate 420 are located at two opposite sides of the circuit substrate 410 separately. That is, the surface 410f of the circuit substrate 410 backs onto the surface 420f of the metal substrate 420. It is worth mentioning, the openings 410t of the circuit substrate 410 and the metal pillars 450 do not overlap each other.

In the embodiment, the semiconductor package module 400 further includes the electronic component 430 and the electronic component 440. The electronic component 430 is disposed on the metal substrate 420 and located inside the opening 410t of the circuit substrate 410. On the other hand, the electronic component 440 is disposed on the surface 410f of the circuit substrate 410. The electronic component 430 and the electronic component 440 are electrically connected to the circuit substrate 410. It is worth mentioning, in the embodiment, both of the electronic component 430 and the electronic component 440 are not electrically connected to the metal substrate 420.

The electronic component 430 and the electronic component 440 may be active components, such as transistors, or may be passive components, such as capacitors or inductors. For example, in the embodiment, the electronic component 430 is a packaged chip or an unpackaged die, while the electronic component 440 is a capacitor or an inductor. However, the sorts of the electronic component 430 and the electronic component 440 are not limited to the embodiment.

The semiconductor package module 400 further includes the encapsulation layer 460, and the encapsulation layer 460 is disposed on the surface 410f of the circuit substrate 410 and covers the electronic component 430 and the electronic component 440. The encapsulation layer 460 encapsulates the metal pillars 450 and has the top surface 460t backing onto the circuit substrate 410, while the edge surface ED2 of the metal pillars 450 is exposed on the top surface 460t of the encapsulation layer 460. Thus, the semiconductor package module 400 may be electrically connected to other components, such as main board, through the edge surface ED2 of the metal pillars 450.

In conclusion, the metal substrate of at least one embodiment of the disclosure is disposed on one of the surfaces of the circuit substrate, and the metal substrate directly touches the surface of the circuit substrate. The circuit substrate includes a plurality of openings which the two opposite sides of the circuit substrate is connected to each other through, while the metal substrate covers one end of each opening. As a result, when the electronic components (e.g., the electronic component 130 or the electronic component 140) are disposed on the surface of the metal substrate and located inside the openings of the circuit substrate, the metal substrate may provide the heat dissipation path which is advantage for increasing the heat dissipation efficiency of the semiconductor package module. Therefore, embedding the metal bulks inside the circuit substrate to improve the heat dissipation of the semiconductor package module is unnecessary. Thus, the uneven interface which is caused by the embedded metal bulks and is located between the circuit substrate and the metal substrate for heat dissipation may be prevented, thereby improving the assembly yield of the semiconductor package module.

Although the embodiments of the present disclosure have been disclosed as above in the embodiments, they are not intended to limit the embodiments of the present disclosure. Any person having ordinary skill in the art can make various changes and modifications without departing from the spirit and the scope of the embodiments of the present disclosure. Therefore, the protection scope of the embodiments of the present disclosure should be determined according to the scope of the appended claims.

What is claimed is:

1. A method for fabrication of a semiconductor package module, comprising:
providing a circuit substrate, and the circuit substrate comprises a first surface;
providing a metal substrate, and the metal substrate comprises a second surface;
removing a part of the circuit substrate to form at least a first opening on the circuit substrate, and two opposite sides of the circuit substrate are connected to each other through the first opening;
removing a part of the metal substrate to form at least a second opening on the metal substrate, and two opposite sides of the metal substrate is connected to each other through the second opening;
disposing a plurality of first metal pillars on the first surface of the circuit substrate; and
disposing the metal substrate on the first surface of the circuit substrate after the first opening and the second opening is formed, and the second surface of the metal substrate faces the first surface of the circuit substrate, wherein the first opening of the circuit substrate and the second opening of the metal substrate do not overlap each other, and the plurality of first metal pillars are located inside the second opening of the metal substrate.

2. The method of claim 1, further comprising:
disposing a first electronic component on the second surface of the metal substrate, and the first electronic component is located inside the first opening of the circuit substrate, wherein the first electronic component is electrically connected to the circuit substrate.

3. The method of claim 2, further comprising:
disposing a second electronic component on a third surface of the circuit substrate after the first electronic component is disposed on the second surface of the metal substrate, wherein the first surface and the third surface are located at two opposite sides of the circuit substrate separately, and the second electronic component is electrically connected to the circuit substrate.

4. The method of claim 3, further comprising:
disposing a plurality of second metal pillars on the third surface after the second electronic is disposed on the third surface of the circuit substrate, wherein an edge surface of each of the plurality of second metal pillars protrudes from a plane of the second electronic component, and the edge surface and the plane back onto the circuit substrate.

5. The method of claim 4, further comprising:
disposing an encapsulation material on the third surface to encapsulate the first electronic component, the second electronic component and the plurality of second metal pillars after the plurality of second metal pillars are disposed on the third surface of the circuit substrate; and
grinding the encapsulation material to form an encapsulation layer after the encapsulation material is disposed, and the encapsulation layer covers the first electronic component and the second electronic component, wherein the edge surface of the plurality of second metal pillars is exposed on a top surface of the encapsulation layer, and the top surface backs onto the circuit substrate.

6. A method for fabrication of a semiconductor package module, comprising:
providing a circuit substrate, and the circuit substrate comprises a first surface;
providing a metal substrate, and the metal substrate comprises a second surface;
removing a part of the circuit substrate to form at least an opening on the circuit substrate, and two opposite sides of the circuit substrate are connected to each other through the opening;
disposing a plurality of metal pillars on the first surface of the circuit substrate; and
disposing the circuit substrate on the second surface of the metal substrate, and the first surface of the circuit substrate backs onto the second surface of the metal substrate, wherein the opening of the circuit substrate and the plurality of metal pillars do not overlap each other.

7. The method of claim 6, further comprising:
disposing a first electronic component on the second surface of the metal substrate after the circuit substrate is disposed on the second surface of the metal substrate, and the first electronic component is located inside the opening of the circuit substrate, wherein the first electronic component is electrically connected to the circuit substrate.

8. The method of claim 7, further comprising:
disposing a second electronic component on the first surface of the circuit substrate after the circuit substrate is disposed on the second surface of the metal substrate, and the second electronic component is electrically connected to the circuit substrate.

9. The method of claim 8, wherein an edge surface of each of the plurality of metal pillars protrudes from a plane of the second electronic component, and the edge surface and the plane back onto the circuit substrate.

10. The method of claim 9, further comprising:
disposing an encapsulation material on the first surface to encapsulate the first electronic component, the second electronic component and the plurality of metal pillars after the second electronic component is disposed on the first surface of the circuit substrate; and
grinding the encapsulation material to form an encapsulation layer after the encapsulation material is disposed, and the encapsulation layer covers the first electronic component and the second electronic component, wherein the edge surface of the plurality of metal pillars is exposed on a top surface of the encapsulation layer, and the top surface backs onto the circuit substrate.

11. A semiconductor package module, comprising:
a circuit substrate comprising a first opening, wherein two opposite sides of the circuit substrate are connected to each other through the first opening;
a metal substrate disposed on a first surface of the circuit substrate, wherein a second surface of the metal substrate faces the circuit substrate, and the metal substrate comprises a second opening, wherein two opposite sides of the metal substrate are connected to each other through the second opening, and the second opening of the metal substrate and the first opening of the circuit substrate do not overlap each other; and
a plurality of first metal pillars disposed on the first surface of the circuit substrate and located inside the second opening of the metal substrate.

12. The semiconductor package module of claim 11, wherein the plurality of first metal pillars are completely spaced from an inner wall of the second opening of the metal substrate.

13. The semiconductor package module of claim 11, wherein the metal substrate further comprises at least one trench, and the two opposite sides of the metal substrate are connected to each other through the trench, wherein at least two regions of the metal substrate are completely spaced from each other by the trench.

14. The semiconductor package module of claim 11, further comprising:
a first electronic component disposed on the second surface of the metal substrate and located inside the first opening of the circuit substrate, wherein the first electronic component is electrically connected to the circuit substrate.

15. The semiconductor package module of claim 14, further comprising:
a second electronic component disposed on a third surface of the circuit substrate, and the third surface and the first surface are located at the two opposite sides of the circuit substrate separately, wherein the second electronic component is electrically connected to the circuit substrate.

16. The semiconductor package module of claim 15, further comprising:
a plurality of second metal pillars disposed on the third surface of the circuit substrate, wherein an edge surface of each of the plurality of second metal pillars protrudes from a plane of the second electronic component, and the edge surface and the plane back onto the circuit substrate; and
an encapsulation layer disposed on the third surface of the circuit substrate and covering the first electronic component and the second electronic component, wherein the edge surface of the plurality of second metal pillars is exposed on a top surface of the encapsulation layer, and the top surface backs onto the circuit substrate.

17. A semiconductor package module, comprising:
a circuit substrate comprising a first surface and a first opening, wherein two opposite sides of the circuit substrate are connected to each other through the first opening;
a metal substrate disposed on the circuit substrate, wherein a second surface of the metal substrate faces the circuit substrate; and
a plurality of metal pillars disposed on the first surface of the circuit substrate, wherein the first surface of the circuit substrate and the second surface of the metal substrate are located at two opposite sides of the circuit substrate, wherein the first opening of the circuit substrate and the plurality of metal pillars do not overlap each other.

18. A semiconductor system, comprising:
a semiconductor package module of claim 11; and
a main board disposed on the metal substrate, wherein the metal substrate is located between the circuit substrate and the main board, and the main board is electrically connected to the circuit substrate through the plurality of first metal pillars.

19. A semiconductor system, comprising:
a semiconductor package module of claim 17, and the semiconductor package module further comprising:
an encapsulation layer disposed on the first surface of the circuit substrate and encapsulating the plurality of metal pillars, wherein an edge surface of the plurality of metal pillars is exposed on a top surface of the encapsulation layer, and the top surface backs onto the circuit substrate; and
a main board disposed on the top surface of the encapsulation layer, wherein the main board is connected to the edge surface of the plurality of metal pillars, and the main board is electrically connected to the circuit substrate through the plurality of metal pillars.
